(19) United States
(12) Patent Application Publication
(10) Pub. No.: US 2015/0055312 A1
(43) Pub. Date: Feb. 26, 2015

(54) INTERPOSER SUBSTRATE AND METHOD OF MANUFACTURING THE SAME

(71) Applicant: Samsung Electro-Mechanics Co., Ltd., Suwon (KR)

(72) Inventors: Jeong Ho LEE, Suwon (KR); Mi Jin PARK, Suwon (KR); Chang Bae LEE, Yongin (KR); Young Do KWEON, Suwon (KR)

(73) Assignee: Samsung Electro-Mechanics Co., Ltd., Suwon (KR)

(21) Appl. No.: 14/250,965

(22) Filed: Apr. 11, 2014

(30) Foreign Application Priority Data
Aug. 22, 2013 (KR) 10-2013-0099697

(51) Int. Cl. H05K 1/11; H05K 13/04; H05K 3/10; B23K 1/00; H05K 1/18; H05K 3/18

(52) U.S. Cl. CPC H05K 1/116; H05K 1/18; H05K 3/188; H05K 3/107; B23K 1/0016; H05K 13/0465; B23K 2001/12; H05K 2203/041; H05K 2203/107
USPC 361/783; 174/262; 205/125; 427/97.2; 228/246; 427/555; 228/170

(57) ABSTRACT

Disclosed herein is an interposer substrate, including: a core layer and a through core via (TCV) penetrating through the core layer; circuit wirings formed on both surfaces of the core layer and a TCV upper pad and a TCV lower pad which are each bonded to upper and lower surfaces of the TCV formed on both surfaces of the core layer; upper insulating layers covering the TCV upper pad and the circuit wiring formed on one surface of the core layer and having the circuit wirings formed on upper surfaces thereof; a stack via penetrating through the upper insulating layers of each layer and having one end connected to the TCV upper pad; and a lower insulating layer covering the TCV lower pad and the circuit wiring formed on the other surface of the core layer and provided with an opening which exposes the TCV lower pad.

This application claims the foreign priority benefit under 35 U.S.C. Section 119 of Korean Patent Application Serial No. 10-2013-0099697 entitled “Interposer Substrate And Method Of Manufacturing The Same” filed on Aug. 22, 2013, which is hereby incorporated by reference in its entirety into this application.

### BACKGROUND OF THE INVENTION

1. Technical Field

The present invention relates to an interposer substrate and a method of manufacturing the same, and more particularly, to an interposer substrate with improved electrical characteristics and a method of manufacturing the same.

2. Description of the Related Art

A main trend of technology development in a semiconductor industry implements a light, small, fast, multi-functional, high-performance, and high-reliability semiconductor device. One of the important technologies capable of implementing the semiconductor devices is the very package technology. To this end, a need exists for an interposer technology capable of securing the reliability of the package.

For example, the semiconductor device is mounted on a main substrate made of a glass epoxy material and then is subjected to soldering. In the case of manufacturing the semiconductor package, there is a need to heat the main substrate and the semiconductor device to a solder melting temperature. In this case, a coefficient of thermal expansion of the main substrate made of the glass epoxy material is different from a coefficient of thermal expansion of the semiconductor device made of silicon, such that cracks may occur at a connection part between the main substrate and the semiconductor device and after the soldering processing is completed, the semiconductor device may be damaged when the main substrate and the semiconductor device are cooled.

Therefore, for the purpose of solving the problem occurring due to the difference between the coefficient of thermal expansion between the main substrate and the semiconductor device, in order to achieve the electrical connection between the main substrate and the semiconductor device while relieving a stress occurring due to the difference in the coefficient of thermal expansion between the main substrate and the semiconductor device, a so-called silicon interposer to hold a silicon substrate made of the same material as the semiconductor device between the main substrate and the semiconductor device has been known (Korean Patent Laid-Open Publication No. 10-2006-0050797).

However, for the electrical connection between the main substrate and the semiconductor device, there is a need to design circuit wirings on a core layer and insulating layers on upper and lower portions thereof which are a basic structure of the interposer, such that a total number of layers of the interposer may be increased, thereby making it difficult to implement miniaturization and thinness of a product.

Further, since the main substrate is electrically connected to the semiconductor device via the circuit wirings of each layer, the interposer substrate has a structure in which a connection path has no choice but to be long, thereby limiting improvement in electrical performance.

### RELATED ART DOCUMENT

### Patent Document

(Patent Document 1) Patent Document: Korean Patent Laid-Open Publication No. 10-2006-0050797

### SUMMARY OF THE INVENTION

An object of the present invention is to provide an interposer substrate having an advantage in thinness and miniaturization while increasing electrical characteristics between a main substrate and a semiconductor device which are connected to each other via an interposer, and a method of manufacturing the same.

According to an exemplary embodiment of the present invention, there is provided an interposer substrate, including: a core layer and a through core via (TCV) penetrating through the core layer in a thickness direction; circuit wirings formed on both surfaces of the core layer and a TCV upper pad and a TCV lower pad which are each bonded to upper and lower surfaces of the TCV formed on both surfaces of the core layer; upper insulating layers covering the TCV upper pad and the circuit wiring formed on one surface of the core layer and having the circuit wirings formed on upper surfaces thereof; a stack via penetrating through the upper insulating layers of each layer and having one end connected to the TCV upper pad; and a lower insulating layer covering the TCV lower pad and the circuit wiring formed on the other surface of the core layer and provided with an opening which exposes the TCV lower pad.

The upper insulating layer may be configured of a dual layer of at least two layers.

The interposer substrate may further include a solder ball formed in the opening formed on the lower insulating layer and connected to the TCV lower pad, wherein the interposer substrate is electrically connected to a main substrate through the solder ball.

A diameter of the stack via may be formed to be smaller than that of the TCV.

A surface roughness Ra of the circuit wiring formed on the upper surface of the upper insulating layer may be smaller than the surface roughness Ra of the circuit wirings formed on both surfaces of the core layer.

The interposer substrate may further include: a semiconductor chip which is embedded in the core layer and the upper insulating layer and is electrically connected to an external device through a connection electrode formed on an upper surface thereof.

According to another exemplary embodiment of the present invention, there is provided a method of manufacturing an interposer substrate, including: forming a TCV penetrating through a core layer in a thickness direction; coating an upper insulating layer on one surface of the core layer; forming a blind via, which is connected to the TCV and is a configuration of a stack via, on the upper insulating layer; building-up the upper insulating layer including the blind vias as many as a predetermined number of layers so that the blind vias of each layer are connected in a straight line; and coating a lower insulating layer on the other surface of the core layer and forming an opening exposing the TCV on the lower insulating layer.

The method of manufacturing an interposer substrate may include: after the forming of the opening exposing the TCV on the lower insulating layer, forming a solder ball for connecting with a main substrate in the opening.

The method of manufacturing an interposer substrate may further include: attaching a cover film to the other surface of the core layer prior to coating the upper insulating layer and removing the cover film prior to coating the lower insulating layer after the upper insulating layer is coated.

In the forming of the TCV, a via hole penetrating through the core layer may be formed using mechanical drilling or laser drill and then an inside of the via hole may be filled with metal by a plating process.

The forming of the blind via may include: forming a via hole on the upper insulating layer at a position at which the blind via is formed, by a photolithography method; forming a seed layer on a surface of the insulating layer including an inner wall of the via hole; attaching a photo resist pattern on the seed layer; electroplating the seed layer as a lead-in wire; and delaminating the photo resist pattern and then etching a seed layer at a portion to which the photo resist pattern is attached.

The method of manufacturing an interposer substrate may further include: building-up the upper insulating layer including the blind via as many as a predetermined number of layers, machining a cavity penetrating through the stacked upper insulating layer and core layer, and mounting the semiconductor chip in the cavity.

### BRIEF DESCRIPTION OF THE DRAWINGS

FIG. 1 is a cross-sectional view illustrating an interposer substrate according to an exemplary embodiment of the present invention.

FIG. 2 is a cross-sectional view of an interposer substrate according to another exemplary embodiment of the present invention.

FIGS. 3 to 9 are process diagrams sequentially illustrating a method of manufacturing an interposer substrate according to an exemplary embodiment of the present invention.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art.

Terms used in the present specification are for explaining exemplary embodiments rather than limiting the present invention. Unless explicitly described to the contrary, a singular form includes a plural form in the present specification. Further, the word “constituents”, “steps”, “operations”, and/or “elements” mentioned herein will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

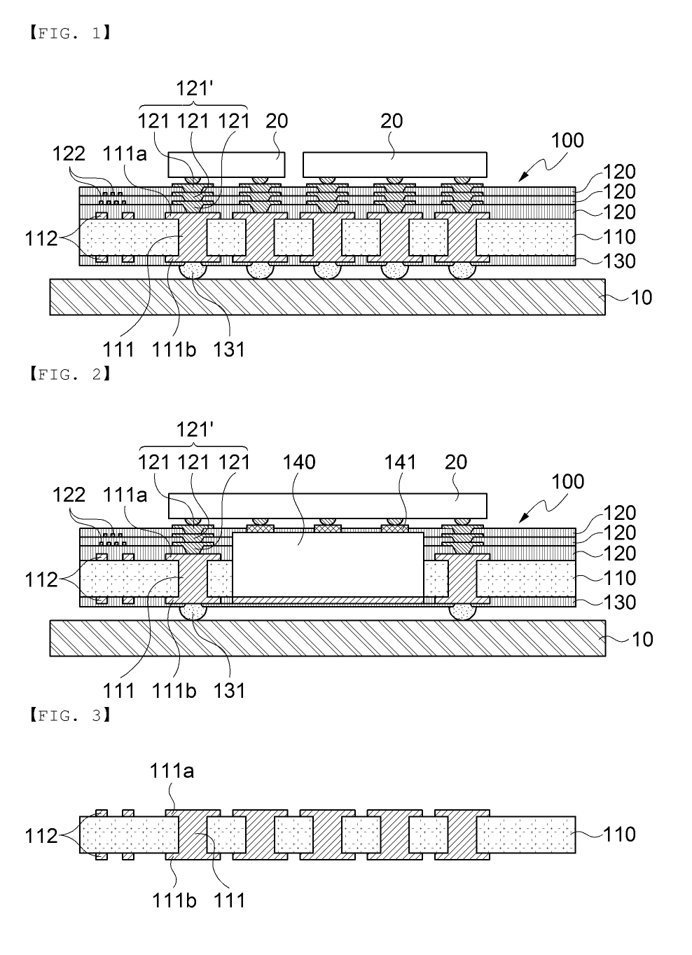

FIG. 1 is a cross-sectional view illustrating an interposer substrate according to an exemplary embodiment of the present invention. Additionally, components shown in the accompanying drawings are not necessarily shown to scale. For example, sizes of some components shown in the accompanying drawings may be exaggerated as compared with other components in order to assist in the understanding of the exemplary embodiments of the present invention. Meanwhile, throughout the accompanying drawings, the same reference numerals will be used to describe the same components. For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure.

Referring to FIG. 1, an interposer substrate 100 according to an exemplary embodiment of the present invention includes a core layer 110 and an upper insulating layer 120 which is formed on one surface of the core layer 110 and a lower insulating layer 130 which is formed on the other surface thereof, as a basic structure.

The core layer 110 is a substrate which supports various components on upper and lower portions thereof and may be made of known resins such as a glass epoxy resin, a bismaleimide-triazine (BT) resin, a polyimide resin, and a fluorinated resin.

Both surfaces of the core layer 110 may be provided with circuit wirings 112 made of any one metal of Ni, Al, Fe, Cu, Ti, Cr, Au, Ag, and Pd, all of which have excellent conductivity.

The circuit wiring 112 may be configured of a ground circuit which forms a ground area, a power supply circuit which is a means of supplying power, a signal circuit which serves as an electrical path to transfer a signal, and the like, according to the usage. Generally, the circuit wiring 112 formed on the core layer 110 may be the power supply circuit or the ground circuit having a metal content larger than that of the signal circuit.

Further, a predetermined position of the core layer 110 may be provided with a through core via (hereinafter, referred to as TCV) 111 which penetrates through the core layer 110 in a thickness direction and both surfaces of the core layer 110 at a position at which the TCV 111 is formed may be provided with a TCV upper pad 111a and a TCV lower pad 111b which are bonded to upper and lower surfaces of the TCV 111, respectively.

An inter-layer electrical connection is made by the TCV 111. In addition to the TCV 111, the TCV upper pad 111a, the TCV lower pad 111b, and the circuit wiring 112 may be formed by a general substrate manufacturing process, which will be described in detail in a method of manufacturing an interposer substrate according to an exemplary embodiment of the present invention.

The upper insulating layer 120 which is formed on one surface of the core layer 110 covers the circuit wiring 112 including the TCV upper pad 111a and the lower insulating layer 130 formed on the other surface of the core layer 110 covers the circuit wiring 112 including the TCV lower pad 111b. Here, the upper insulating layer 120 may be stacked in a dual layer of at least two layers and the upper surfaces of the upper insulating layers 120 of each layer may be provided with a blind via 121 penetrating through the circuit wiring 122 and the upper insulating layer 120.

Although being described in detail in the method of manufacturing an interposer substrate according to the exemplary embodiment of the present invention, the circuit wiring 122 in addition to the blind via 121 may be formed by a semiconductor manufacturing process, including a photolithography method. Therefore, the circuit wiring 122 on the upper surface of the upper insulating layer 120 may be implemented in a fine pattern, such that as compared to the related art, a larger number of circuit wirings may be designed and there is no need to design separate circuit wirings on the lower insulating layer 130. As a result, the interposer substrate 100 according to the exemplary embodiment of the present invention has an asymmetrical structure, such that a total number of substrate layers may be reduced as compared to the interposer substrate according to the related art, thereby implementing thinness, reducing the number of processes, and saving production cost.

The blind vias 121 of each layer are connected in a straight line to form a stack via 121′ and one end of the stack via 121′ is connected to the TCV upper pad 111a and the other end thereof may be connected to an external device 20, for example, an IC chip on an upper portion of the interposer substrate 100.

Further, the TCV lower pad 111b may be connected to a main substrate 10 by a solder ball connection. In detail, the lower insulating layer 130 may be provided with openings which expose the TCV lower pad 111b, in which the openings may be provided with conductive solder balls 131. As such, when the external device 20 is electrically connected to the main substrate 10 using the interposer substrate 100 according to the exemplary embodiment of the present invention, the main substrate 10 is directly bonded to the TCV 111 via the solder ball 131 without passing through separate circuit wirings, such that the electrical signal may be maintained at a shortest distance, thereby remarkably improving electrical characteristics.

Meanwhile, as described above, the TCV 111 is formed by the substrate manufacturing process and the stack via 121′ is formed by the semiconductor manufacturing process, such that a diameter of the stack via 121′ may be formed to be smaller than that of the TCV 111. As such, when the diameter of the stack via 121′ is formed to be smaller than that of the TCV 111, a freedom of design of the circuit wiring may be increased and a process margin may be large.

Further, due to the difference in manufacturing process between the TCV 111 and the stack via 121′, the circuit wirings 112 on both surfaces of the core layer 110 which is formed simultaneously with forming the TCV 111 and the circuit wiring 122 on the upper surface of the upper insulating layer 120 formed simultaneously with forming the stack via 121′ may be formed to have different surface roughness Ra.

In detail, the surface roughness Ra of the circuit wirings 112 on both surfaces of the core layer 110 and the surface roughness Ra of the circuit wiring 122 on the upper surface of the upper insulating layer 120 are each determined within a range of 300 nm to 600 nm or 1 nm to 10 nm, such that the surface roughness Ra of the circuit wiring 122 on the upper insulating layer 120 may be formed to be smaller than that of the circuit wiring 112 on both surfaces of the core layer 110 depending on each process.

As described above, the circuit wiring is divided into the ground circuit, the power supply circuit, and the signal circuit according to the usage. In general, the core layer 110 is provided with the power supply circuit or the ground circuit having metal content larger than that of the signal circuit and the upper insulating layer 120 is provided with the circuit wirings of the signal circuit. Meanwhile, when the surface roughness is large in the signal circuit, a rugged portion of the surface serves as an antenna and thus electrical characteristics, such as RF characteristics, may deteriorate. Therefore, according to the exemplary embodiment of the present invention, when the surface roughness of the circuit wiring 122 formed on the upper insulating layer 120 is smaller than that of the circuit wirings 112 on both surfaces of the core layer 110, the electrical characteristics may be excellent.

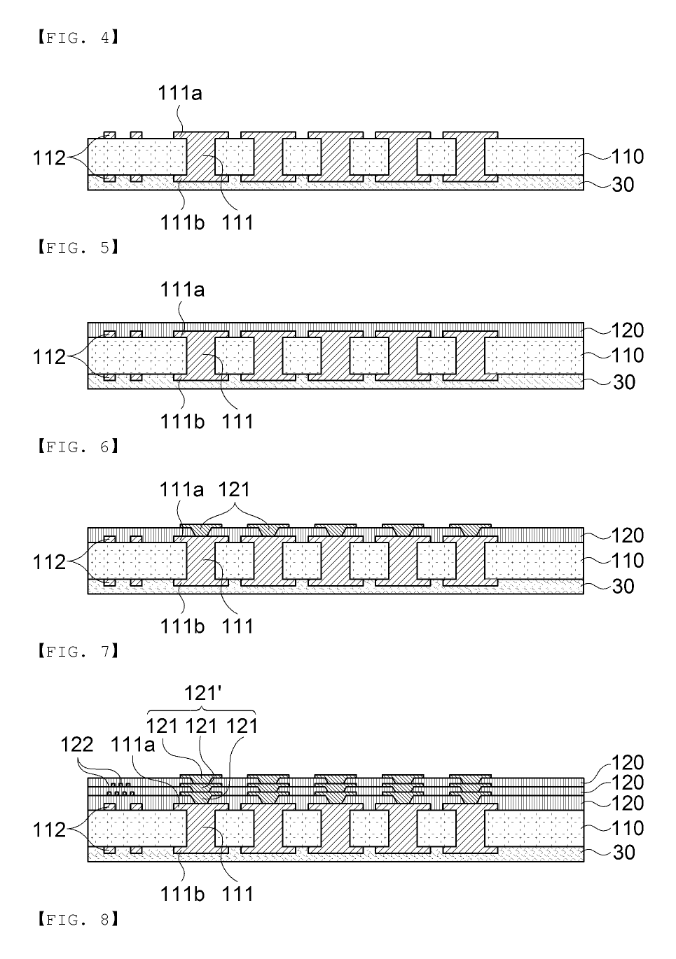

FIG. 2 is a cross-sectional view of the interposer substrate 100 according to another exemplary embodiment of the present invention, and the interposer substrate 100 according to the exemplary embodiment of the present invention may further include a semiconductor chip 140 embedded in the core layer 110 and the upper insulating layer 120.

The upper surface of the semiconductor chip 140 is provided with a connection electrode 141. Through the connection electrode 141, the semiconductor chip 140 may be electrically connected to the external device 20, for example, the IC chip on the upper portion of the interposer substrate 100.

Therefore, two semiconductor chips mounted in the interposer according to the related art are electrically connected to each other through the circuit wiring in the interposer. On the other hand, the semiconductor chip 140 embedded in the interposer substrate 100 according to the exemplary embodiment of the present invention is directly bonded to the external device 20 on the upper portion of the interposer substrate 100 through the connection electrode 141 to maintain the electrical signal at the shortest distance, thereby remarkably improving the electrical characteristics.

Hereinafter, a method of manufacturing an interposer substrate according to the exemplary embodiment of the present invention will be described.

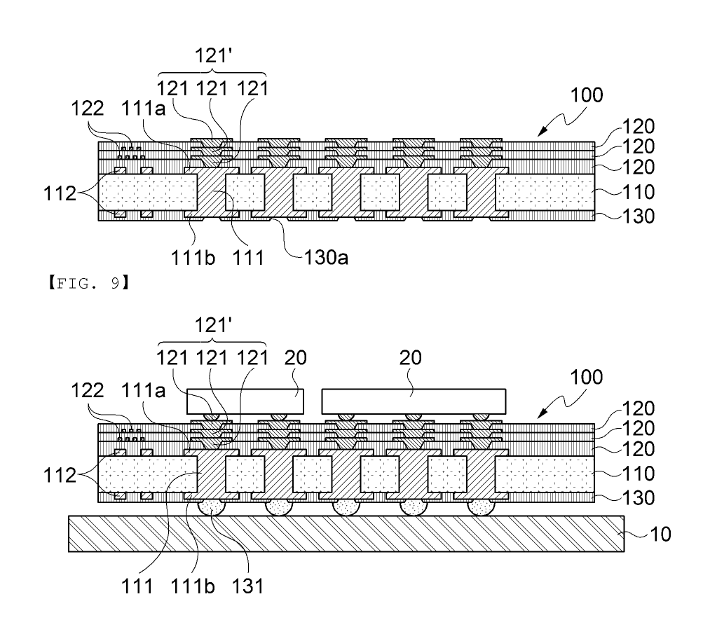

FIGS. 3 to 9 are process diagrams sequentially illustrating the method of manufacturing an interposer substrate according to the exemplary embodiment of the present invention. First, as illustrated in FIG. 3, when the core layer 110 is prepared, the TCV 111 penetrating through the core layer 110 in a thickness direction is formed. Like the substrate manufacturing process, this may be made by forming a via hole at a predetermined position of the core layer 110 using mechanical drilling or laser drill and then filling an inside of the via hole with metal through a plating process. In this case, at the time of the plating process, the TCV upper pad 111a, the TCV lower pad 111b, and the circuit wirings 112 may be plated together.

When the TCV 111 is formed as described above, the upper insulating layer 120 is coated on one surface of the core layer 110. In this case, as illustrated in FIG. 4, prior to coating the upper insulating layer 120, a cover film 30 is attached to the other surface of the core layer 110. The cover film 30, which prevents an insulating material from being coated on the other surface of the core layer 110, may be removed prior to coating the lower insulating layer 130 after the upper insulating layer 120 is coated.

When the cover film 30 is attached, the upper insulating layer 120 is formed using various coating methods, such as a tape casting method, a spin coating method, and an inkjet printing method (FIG. 5) and then is provided with the circuit wiring 122 including the blind via 121 which is a configuration of the stack via 121′ (FIG. 6).

This may be progressed by the semiconductor manufacturing process, unlike the manufacturing of the TCV 111. That is, the via hole is formed on the upper insulating layer 120 at the position at which the blind via 121 is formed, by the photolithography method and a seed layer is formed on the surface of the upper insulating layer 120 including an inner wall of the via hole. Next, the blind via 121 and a photo resist pattern corresponding to the circuit wiring 122 are attached on the seed layer and the seed layer as a lead-in wire is subjected to electroplating. Next, the blind via 121 and the circuit wiring 122 may be completed by delaminating the photo resist pattern and etching the seed layer at a portion to which the photo resist pattern is attached.

Further, as illustrated in FIG. 7, the upper insulating layer 120 including the blind via 121 may be built-up as many as a required predetermined number of layers by repeatedly performing the process. In this case, the stack via 121′ is formed by connecting the blind vias 121 of each layer in a straight line.

When the upper insulating layer 120 is completed as described above, as illustrate in FIG. 8, the cover film 30 is removed, the lower insulating layer 130 covering the circuit wiring 112 including the TCV lower pad 111b is coated on the other surface of the core layer 110, and then the lower insulating layer 130 is provided with an opening 130a which exposes the TCV lower pad 111b.

Further, the interposer substrate 100 of FIG. 8 is electrically connected to the main substrate 10 by forming the solder ball 131 in the opening 130a and the external device 20 is also connected to the interposer substrate 100 by the solder ball bonding, thereby completing the package substrate of FIG. 9.

Meanwhile, the interposer substrate of FIG. 2 may be manufactured by further building-up the upper insulating layer 120 including the blind via 121 as many as a predetermined number of layers, machining a cavity penetrating through the stacked upper insulating layer 120 and core layer 110, and mounting the semiconductor chip 140 in the cavity.

According to the exemplary embodiments of the present invention, the through core via formed on the core layer which is the basic structure of the interposer is directly bonded to the main substrate without passing through the separate circuit wirings to maintain the electrical signal at the shortest distance, thereby remarkably improving the electrical characteristics.

Further, the circuit wirings plated on the insulating layer is formed by the semiconductor manufacturing process to implement the fine pattern, thereby implementing the thinness of the product.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. An interposer substrate, comprising:
a core layer and a through core via (TCV) penetrating through the core layer in a thickness direction;
circuit wirings formed on both surfaces of the core layer and a TCV upper pad and a TCV lower pad which are each bonded to upper and lower surfaces of the TCV formed on both surfaces of the core layer;
upper insulating layers covering the TCV upper pad and the circuit wiring formed on one surface of the core layer and having the circuit wirings formed on upper surfaces thereof;
a stack via penetrating through the upper insulating layers of each layer and having one end connected to the TCV upper pad; and
a lower insulating layer covering the TCV lower pad and the circuit wiring formed on the other surface of the core layer and provided with an opening which exposes the TCV lower pad.

2. The interposer substrate according to claim 1, wherein the upper insulating layer is configured of a dual layer of at least two layers.

3. The interposer substrate according to claim 1, further comprising:
a solder ball formed in the opening formed on the lower insulating layer and connected to the TCV lower pad, wherein the interposer substrate is electrically connected to a main substrate through the solder ball.

4. The interposer substrate according to claim 1, wherein a diameter of the stack via is formed to be smaller than that of the TCV.

5. The interposer substrate according to claim 1, wherein a surface roughness Ra of the circuit wiring formed on the upper surface of the upper insulating layer is smaller than the surface roughness Ra of the circuit wirings formed on both surfaces of the core layer.

6. The interposer substrate according to claim 1, further comprising:
a semiconductor chip which is embedded in the core layer and the upper insulating layer and is electrically connected to an external device through a connection electrode formed on an upper surface thereof.

7. A method of manufacturing an interposer substrate, comprising:
forming a TCV penetrating through a core layer in a thickness direction;
coating an upper insulating layer on one surface of the core layer;
forming a blind via, which is connected to the TCV and is a configuration of a stack via, on the upper insulating layer;
building-up the upper insulating layer including the blind vias as many as a predetermined number of layers so that the blind vias of each layer are connected in a straight line; and
coating a lower insulating layer on the other surface of the core layer and forming an opening exposing the TCV on the lower insulating layer.

8. The method according to claim 7, further comprising:
after the forming of the opening exposing the TCV on the lower insulating layer, forming a solder ball for connecting with a main substrate in the opening.

9. The method according to claim 7, further comprising:
attaching a cover film to the other surface of the core layer prior to coating the upper insulating layer and removing the cover film prior to coating the lower insulating layer after the upper insulating layer is coated.

10. The method according to claim 7, wherein in the forming of the TCV, a via hole penetrating through the core layer is formed using mechanical drilling or laser drill and then an inside of the via hole is filled with metal by a plating process.

11. The method according to claim 7, wherein the forming of the blind via includes:
forming a via hole on the upper insulating layer at a position at which the blind via is formed, by a photolithography method;
forming a seed layer on a surface of the insulating layer including an inner wall of the via hole;
attaching a photo resist pattern on the seed layer;
electroplating the seed layer as a lead-in wire; and
delaminating the photo resist pattern and then etching a seed layer at a portion to which the photo resist pattern is attached.

12. The method according to claim 7, further comprising:
building-up the upper insulating layer including the blind via as many as a predetermined number of layers, machining a cavity penetrating through the stacked upper insulating layer and core layer, and mounting the semiconductor chip in the cavity.
